(19) United States
(12) Patent Application Publication
(10) Pub. No.: US 2025/0218728 A1
(43) Pub. Date: Jul. 3, 2025

(54) SHOWER HEAD ASSEMBLY AND SUBSTRATE TREATING APPARATUS INCLUDING THE SAME

(71) Applicant: SEMES CO., LTD., Cheonan-si (KR)

(72) Inventors: Tae Guen PARK, Chungcheongnam-do (KR); Dong Won KANG, Chungcheongnam-do (KR)

(73) Assignee: SEMES CO., LTD., Cheonan-si (KR)

(21) Appl. No.: 18/938,634

(22) Filed: Nov. 6, 2024

(30) Foreign Application Priority Data
Dec. 29, 2023 (KR) 10-2023-0196329

(51) Int. Cl. H01J 37/32

(52) U.S. Cl. CPC H01J 37/3244; H01J 2237/332; H01J 2237/334

(57) ABSTRACT

Provided are a shower head assembly that is easy to replace and may maintain a fastening force even under repeated thermal shock, and a substrate treating apparatus including the same. The substrate treating apparatus includes: a chamber housing providing a space for treating a substrate; a substrate support unit disposed inside the chamber housing and supporting the substrate; a shower head assembly disposed inside the chamber housing and providing a process gas; and a plasma generation unit generating plasma for treating the substrate using the process gas, wherein the shower head assembly includes: a lower plate; a shower head disposed on the lower plate; a gas distribution plate disposed on the shower head; and an upper plate disposed on the gas distribution plate, and the shower head is detachable and attachable.

### CROSS-REFERENCE TO RELATED APPLICATION

This application claims priority from Korean Patent Application No. 10-2023-0196329 filed on Dec. 29, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a shower head assembly applied to a facility for treating a substrate using plasma and a substrate treating apparatus including the same.

### 2. Description of the Related Art

The substrate treating apparatus may include a shower head to supply a process gas and generate plasma. The shower head may be fastened to a base plate, a gas distribution plate, etc., and may be provided to an upper electrode module within the substrate treating apparatus through such a fastening.

However, since the shower head is fastened to the base plate, the gas distribution plate, etc. using bolts, the fastening force may be weakened by thermal shock resulting from the repeated substrate treatment process. In addition, since the shower head has a complicated assembly process, it is not easy to replace.

### SUMMARY

Aspects of the present disclosure provide a shower head assembly that is easy to replace and may maintain a fastening force even under repeated thermal shock, and a substrate treating apparatus including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate treating apparatus including: a chamber housing providing a space for treating a substrate; a substrate support unit disposed inside the chamber housing and supporting the substrate; a shower head assembly disposed inside the chamber housing and providing a process gas; and a plasma generation unit generating plasma for treating the substrate using the process gas, wherein the shower head assembly includes: a lower plate; a shower head disposed on the lower plate; a gas distribution plate disposed on the shower head; and an upper plate disposed on the gas distribution plate, and the shower head is detachable and attachable.

According to another aspect of the present disclosure, there is provided a shower head assembly providing a process gas into a substrate treating apparatus, the shower head assembly includes: a lower plate; a shower head disposed on the lower plate; a gas distribution plate disposed on the shower head; and an upper plate disposed on the gas distribution plate, wherein the shower head includes: a first plate; and a second plate disposed on the first plate and engaged with the first plate, the shower head is detachable and attachable, and when the shower head is replaced, the lower plate, the gas distribution plate, and the upper plate are not separated within the substrate treating apparatus.

According to another aspect of the present disclosure, there is provided a substrate treating apparatus including: a chamber housing providing a space for treating a substrate; a substrate support unit disposed inside the chamber housing and supporting the substrate; a shower head assembly disposed inside the chamber housing and providing a process gas; and a plasma generation unit generating plasma for treating the substrate using the process gas, wherein the shower head assembly includes: a lower plate; a shower head disposed on the lower plate; a gas distribution plate disposed on the shower head; and an upper plate disposed on the gas distribution plate, the shower head includes: a first plate; and a second plate disposed on the first plate and engaged with the first plate, the first plate and the second plate are inserted between the lower plate and the gas distribution plate while being engaged with each other, the second plate is inserted between the lower plate and the gas distribution plate, and then slides inwardly in the substrate treating apparatus, and when the shower head is replaced, the lower plate, the gas distribution plate, and the upper plate are not separated within the substrate treating apparatus.

The details of other exemplary embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view exemplarily illustrating an internal structure of a semiconductor manufacturing facility according to a first exemplary embodiment;

FIG. 2 is a plan view exemplarily illustrating an internal structure of a semiconductor manufacturing facility according to a second exemplary embodiment;

FIG. 3 is a plan view exemplarily illustrating an internal structure of a semiconductor manufacturing facility according to a third exemplary embodiment;

FIG. 4 is a cross-sectional view exemplarily illustrating an internal structure of a substrate treating apparatus according to a first exemplary embodiment;

FIG. 5 is a cross-sectional view exemplarily illustrating an internal structure of a substrate treating apparatus according to a second exemplary embodiment;

FIG. 6 is a cross-sectional view exemplarily illustrating an internal structure of a substrate treating apparatus according to a third exemplary embodiment;

FIG. 7 is an exemplary view for describing a structure of a shower head assembly according to an exemplary embodiment of the present disclosure;

FIG. 8 is an exemplary view for describing a structure of a lower plate constituting the shower head assembly according to an exemplary embodiment of the present disclosure;

FIG. 9 is an exemplary view for describing a structure of a shower head according to a first exemplary embodiment of the present disclosure;

FIG. 10 is a first exemplary view for describing a first plate constituting the shower head according to the first exemplary embodiment of the present disclosure;

FIG. 11 is a second exemplary view for describing the first plate constituting the shower head according to the first exemplary embodiment of the present disclosure;

FIG. 12 is a first exemplary view for describing a second plate constituting the shower head according to the first exemplary embodiment of the present disclosure;

FIG. 13 is a second exemplary view for describing the second plate constituting the shower head according to the first exemplary embodiment of the present disclosure;

FIG. 14 is a first exemplary view for describing a fastening process between the shower head and the lower plate according to the first exemplary embodiment of the present disclosure;

FIG. 15 is a second exemplary view for describing the fastening process between the shower head and the lower plate according to the first exemplary embodiment of the present disclosure;

FIG. 16 is a third exemplary view for describing the fastening process between the shower head and the lower plate according to the first exemplary embodiment of the present disclosure;

FIG. 17 is an exemplary view for describing a structure of a shower head according to a second exemplary embodiment of the present disclosure; and

FIG. 18 is an exemplary view for describing a structure of an upper plate constituting the shower head assembly according to an exemplary embodiment of the present disclosure.

### DETAILED DESCRIPTION OF THE EMBODIMENTS

Hereinafter, exemplary embodiments of the present disclosure will be described in detail with reference to the accompanying drawings. The same reference numerals are used for the same components in the drawings, and duplicate descriptions thereof are omitted.

The present disclosure relates to a substrate treating apparatus that treats a substrate using plasma and a semiconductor manufacturing facility including a plurality of substrate treating apparatuses. The substrate treating apparatus may include a shower head assembly to supply a process gas and generate plasma. The shower head assembly may be provided to be easily replaceable and to maintain a fastening force even under repeated thermal shocks. Hereinafter, the substrate treating apparatus and the semiconductor manufacturing facility will be first described, followed by a description of the shower head assembly.

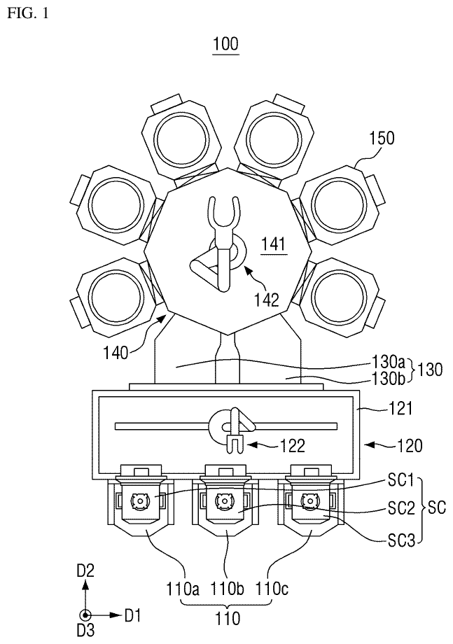

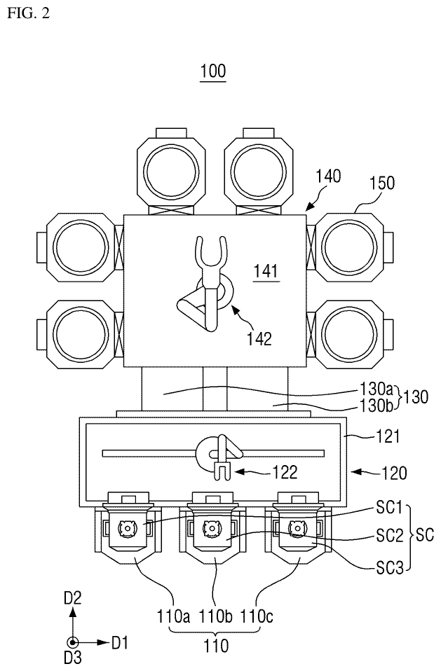

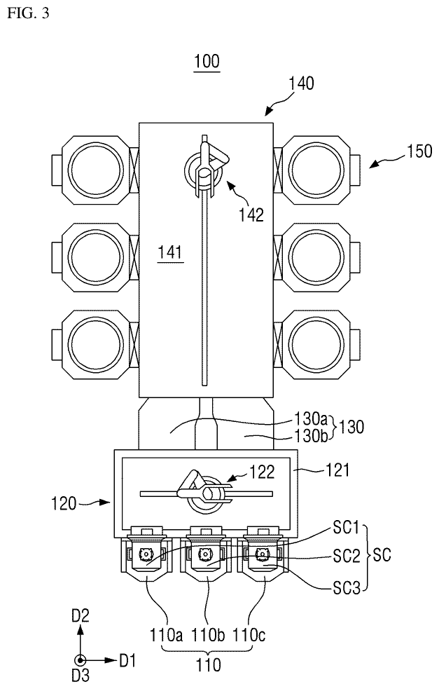

FIG. 1 is a plan view exemplarily illustrating an internal structure of a semiconductor manufacturing facility according to a first exemplary embodiment. FIG. 2 is a plan view exemplarily illustrating an internal structure of a semiconductor manufacturing facility according to a second exemplary embodiment. FIG. 3 is a plan view exemplarily illustrating an internal structure of a semiconductor manufacturing facility according to a third exemplary embodiment.

A first direction D1 and a second direction D2 are horizontal directions and form a plane. For example, the first direction D1 may be a forward-backward direction, and the second direction D2 may be a left-right direction. Alternatively, the first direction D1 may be a left-right direction, and the second direction D2 may be a forward-backward direction. A third direction D3 is a height direction and is a direction perpendicular to the plane formed by the first direction D1 and the second direction D2. The third direction D3 may be an up-down direction.

Referring to FIGS. 1 to 3, a semiconductor manufacturing facility 100 may be configured to include a load port module 110, an index module 120, a load lock chamber 130, a transfer module 140, and a process chamber 150.

The semiconductor manufacturing facility 100 is a system that treats a substrate using an etching process, a cleaning process, a deposition process, etc. The semiconductor manufacturing facility 100 may include one process chamber, but is not limited thereto and may also include a plurality of process chambers. The plurality of process chambers may include process chambers of the same type, but are not limited thereto and may also include process chambers of different types. When the semiconductor manufacturing facility 100 includes the plurality of process chambers, the semiconductor manufacturing facility 100 may be provided as a multi-chamber type substrate treating system.

The load port module 110 is provided so that a container SC on which a plurality of substrates are mounted may be seated. In the above, the container SC may be, for example, a Front Opening Unified Pod (FOUP).

In the load port module 110, the container SC may be loaded or unloaded. In addition, in the load port module 110, the substrate stored in the container SC may be loaded or unloaded.

When the target of loading or unloading is the container SC, a container transport apparatus may load or unload the container SC onto or from the load port module 110. In detail, the container SC may be loaded onto the load port module 110 by seating the container SC that the container transport apparatus was holding onto the load port module 110. In addition, the container SC may be unloaded from the load port module 110 by the container transport apparatus holding the container SC that was seated on the load port module 110. Although not illustrated in FIGS. 1 to 3, the container transport apparatus may be an Overhead Hoist Transporter (OHT).

When the target for loading or unloading is the substrate, a first transport robot 122 may load or unload the substrate onto or from the container SC seated on the load port module 110. In the case of unloading of the substrate, when the container SC is seated on the load port module 110, the first transport robot 122 may approach the load port module 110 and may then carry the substrate out within the container SC. In the case of loading the substrate, when treatment of the substrate is completed within the process chamber 150, the first transport robot 122 may carry the substrate out within the load lock chamber 130 and then carry the substrate in the container SC.

A plurality of load port modules 110 may be disposed in front of the index module 120. For example, three load port modules 110a, 110b, and 110c, such as a first load port module 110a, a second load port module 110b, and a third load port module 110c, may be disposed in front of the index module 120.

When the plurality of load port modules 110 are disposed in front of the index module 120, different types of items may be mounted on the container SC mounted on each load port module. For example, when the first load port module 110a, the second load port module 110b, and the third load port module 110c are disposed in front of the index module 120, a wafer-type sensor may be mounted on a first container SC1 seated on the first load port module 110a, a substrate, i.e., a wafer, may be mounted on a second container SC2 seated on the second load port module 110b, and consumable parts such as a focus ring and an edge ring may be mounted on a third container SC3 seated on the third load port module 110c.

However, the present exemplary embodiment is not limited thereto. The same type of items may also be mounted on the containers SC seated on each load port module. Alternatively, the same type of items may be mounted on containers seated on some load port modules among the plurality of load port modules, and different types of items may also be mounted on containers seated on some other load port modules.

The index module 120 may be disposed between the load port module 110 and the load lock chamber 130 and may be provided as an interface to transfer the substrate between the container SC on the load port module 110 and the load lock chamber 130.

The index module 120 may include a first module housing 121 and a first transport robot 122. The first transport robot 122 may be disposed inside the first module housing 121 and may transport the substrate between the load port module 110 and the load lock chamber 130. The first module housing 121 may have an internal environment provided as an atmospheric pressure environment, and the first transport robot 122 may operate in the atmospheric pressure environment. One first transport robot 122 may be provided within the first module housing 121, but the present disclosure is not limited thereto and a plurality of first transport robots 122 may also be provided.

Although not illustrated in FIGS. 1 to 3, the index module 120 may include a buffer chamber. The buffer chamber may temporarily store untreated substrates before transporting the untreated substrates to the load lock chamber 130. In addition, the buffer chamber may temporarily store pretreated substrates before transporting the pretreated substrates to the container SC on the load port module 110. The buffer chamber may be provided on side walls other than a side wall adjacent to the load port module 110 or a side wall adjacent to the load lock chamber 130, but is not limited thereto and may also be provided on the side wall adjacent to the load port module 110. Alternatively, the buffer chamber may be provided on the side wall adjacent to the load lock chamber 130.

In the present exemplary embodiment, a front end module (FEM) may be provided on one side of the load lock chamber 130. The front end module (FEM) may include the load port module 110 and the index module 120, and may be provided as, for example, an equipment front end module (EFEM).

As described above, the plurality of load port modules 110 may be provided within the semiconductor manufacturing facility 100. Referring to the examples of FIGS. 1 to 3, the plurality of load port modules may have a structure in which they are arranged in the horizontal direction D1. However, the plurality of load port modules are not limited thereto, and may also have a structure in which they are stacked in the vertical direction D3. When the plurality of load port modules are stacked in the vertical direction, the front end module may be provided as a vertically stacked EFEM.

The load lock chamber 130 may serve as a buffer chamber between an input port and an output port within the semiconductor manufacturing facility 100. That is, the load lock chamber 130 may serve to temporarily store the untreated substrates or the pretreated substrates between the load port module 110 and the process chamber 150. Although not illustrated in FIGS. 1 to 3, the load lock chamber 130 may include a buffer stage for temporarily storing the substrate therein.

A plurality of load lock chambers 130 may be disposed between the index module 120 and the transfer module 140. For example, two load lock chambers 130a and 130b, such as a first load lock chamber 130a and a second load lock chamber 130b, may be disposed between the index module 120 and the transfer module 140.

The plurality of load lock chambers may be disposed in the same direction as the arrangement direction of the plurality of load port modules. Referring to the examples of FIGS. 1 to 3, the first load lock chamber 130a and the second load lock chamber 130b may be disposed in the same direction as the arrangement direction of the three load port modules 110a, 110b, and 110c between the index module 120 and the transfer module 140, that is, in the horizontal direction D1. The first load lock chamber 130a and the second load lock chamber 130b may be provided as a mutually symmetrical single-layer structure spaced apart from each other in the horizontal direction.

However, the present exemplary embodiment is not limited thereto. The plurality of load lock chambers may also be disposed in a direction different from the arrangement direction of the plurality of load port modules. The first load lock chamber 130a and the second load lock chamber 130b may be disposed in a direction different from the arrangement direction of the three load port modules 110a, 110b, and 110c between the index module 120 and the transfer module 140, that is, in the vertical direction D3. The first load lock chamber 130a and the second load lock chamber 130b may be provided in a double-layer structure spaced apart from each other in the up-down direction.

Either of the first load lock chamber 130a and the second load lock chamber 130b may temporarily store an untreated substrate being transported from the index module 120 to the transfer module 140. In addition, the other load lock chamber may temporarily store a pretreated substrate being transported from the transfer module 140 to the index module 120. However, the first load lock chamber 130a and the second load lock chamber 130b are not limited thereto, and may also perform both the role of temporarily storing the untreated substrates and the role of temporarily storing the pretreated substrates in common.

The load lock chamber 130 may change the inside thereof into either a vacuum environment or an atmospheric pressure environment using a gate valve or the like. In detail, when the first transport robot 122 of the index module 120 loads the substrate into the load lock chamber 130 or the first transport robot 122 unloads the substrate from the load lock chamber 130, the load lock chamber 130 may have the inside thereof formed into an environment identical or similar to the internal environment of the index module 120. In addition, when the second transport robot 142 of the transfer module 140 loads the substrate into the load lock chamber 130 or the second transport robot 142 unloads the substrate from the load lock chamber 130, the load lock chamber 130 may have the inside thereof formed into an environment identical or similar to the internal environment of the transfer module 140. Through this, the load lock chamber 130 may prevent an internal pressure state of the index module 120 or an internal pressure state of the transfer module 140 from changing.

The transfer module 140 may be disposed between the load lock chamber 130 and the process chamber 150, and may be provided as an interface to allow the substrate to be transferred between the load lock chamber 130 and the process chamber 150.

The transfer module 140 may include a second module housing 141 and a second transport robot 142. The second transport robot 142 may be disposed inside the second module housing 141 and may transport the substrate between the load lock chamber 130 and the process chamber 150. The second module housing 141 may have an internal environment provided as a vacuum environment, and the second transport robot 142 may operate in the vacuum environment. One second transport robot 142 may be provided within the second module housing 141, but the present disclosure is not limited thereto and a plurality of second transport robots 142 may also be provided.

The transfer module 140 may be connected to a plurality of process chambers 150. To this end, the second module housing 141 may include a plurality of sides, and the second transport robot 142 may be provided to be freely rotated through each side of the second module housing 141 to load the substrate into or unload the substrate from the plurality of process chambers 150.

The process chamber 150 serves to treat the substrate. When an untreated substrate is provided, the process chamber 150 may treat the substrate, and may provide the pretreated substrate to the load lock chamber 130 through the transfer module 140. The process chamber 150 will be described in more detail later.

When the semiconductor manufacturing facility 100 includes the plurality of process chambers, the semiconductor manufacturing facility 100 may be formed in a structure having a cluster platform. For example, the plurality of process chambers may be disposed in a cluster manner relative to the transfer module 140 as illustrated in the example of FIG. 1. However, the present exemplary embodiment is not limited thereto. When the semiconductor manufacturing facility 100 includes the plurality of process chambers, the semiconductor manufacturing facility 100 may be formed in a structure having a quad platform. For example, the plurality of process chambers may be disposed in a quad manner relative to the transfer module 140 as illustrated in the example of FIG. 2. Alternatively, when the semiconductor manufacturing facility 100 includes the plurality of process chambers, the semiconductor manufacturing facility 100 may be formed in a structure having an in-line platform. For example, the plurality of process chambers may be disposed in an in-line manner relative to the transfer module 140 as illustrated in the example of FIG. 3, and may be disposed in series with two different process chambers forming a corresponding relationship on both sides of the transfer module 140.

Although not illustrated in FIGS. 1 to 3, the semiconductor manufacturing facility 100 may further include a control device. The control device serves to control the overall operation of each module constituting the semiconductor manufacturing facility 100. For example, the control device may control the substrate transport of the first transport robot 122 or the second transport robot 142, may control changes in the internal environment of the load lock chamber 130, and control the overall substrate treatment process of the process chamber 150.

The control device may include a processor that executes control for each component that constitutes the semiconductor manufacturing facility 100, a network that communicates with each component through wired or wireless communication, one or more instructions relating to a function or operation for controlling each component, a storage means that stores treatment recipes, various data, etc., including the instructions, and the like. The control device may further include a user interface including an input means for an operator to perform command input operations, etc. to manage the semiconductor manufacturing facility 100, an output means for visualizing and displaying an operating status of the semiconductor manufacturing facility 100, and the like. The control device may be provided as a computing device for data processing and analysis, command transmission, etc.

The instructions may be provided in the form of a computer program or application. The computer program may be stored on a computer-readable recording medium, including one or more instructions. The instructions may include code generated by a compiler, code that may be executed by an interpreter, etc. The memory means may be provided as one or more storage media selected from flash memory, HDD, SSD, card type memory, RAM, SRAM, ROM, EEPROM, PROM, magnetic memory, magnetic disk, and optical disk.

Next, the process chamber 150 will be described. The process chamber 150 may have a surface made of alumite with an anodized film formed thereon, and the inside thereof may be airtight. A plurality of process chambers 150 may be provided within the semiconductor manufacturing facility 100, and may be disposed to be spaced apart from each other around the transfer module 140. However, the process chamber 150 is not limited thereto, and may be singly provided within the semiconductor manufacturing facility 100. The process chamber 150 may be provided in a cylindrical shape, but is not limited thereto and may also be provided in a shape other than the cylindrical shape.

As described above, the process chamber 150 may treat the substrate. Hereinafter, the process chamber 150 is defined as a substrate treating apparatus and an internal structure thereof is described.

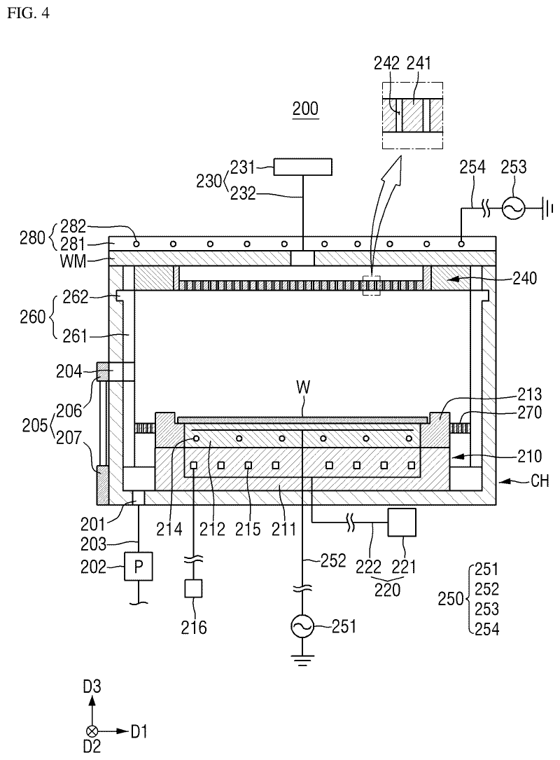

FIG. 4 is a cross-sectional view exemplarily illustrating an internal structure of a substrate treating apparatus according to a first exemplary embodiment. Referring to FIG. 4, a substrate treating apparatus 200 may be configured to include a chamber housing CH, a substrate support unit 210, a cleaning gas supply unit 220, a process gas supply unit 230, a shower head unit 240, a plasma generation unit 250, a liner unit 260, a baffle unit 270, a window module WM, and an antenna unit 280.

The substrate treating apparatus 200 may treat a substrate W. The substrate treating apparatus 200 may treat the substrate W using a dry method. The substrate treating apparatus 200 may treat the substrate W in a vacuum environment, for example. The substrate treating apparatus 200 may treat the substrate W using an etching process. However, the substrate treating apparatus 200 is not limited thereto, and may also treat the substrate W using a deposition process or a cleaning process.

The chamber housing CH provides a space in which a plasma process, i.e., a process of treating the substrate W using plasma, is performed. The chamber housing CH may have a surface made of alumite with an anodized film formed thereon, and the inside thereof may be airtight. The chamber housing CH may be provided in a cylindrical shape, but is not limited thereto and may also be provided in other shapes. The chamber housing CH may have an exhaust hole 201 formed in a lower portion thereof.

The exhaust hole 201 may be connected to an exhaust line 203 equipped with a pump 202. The exhaust hole 201 may discharge process byproducts generated during the plasma process and gases remaining inside the chamber housing CH to the outside of the chamber housing CH through the exhaust line 203. In this case, the internal space of the chamber housing CH may be depressurized.

An opening 204 may be formed to penetrate through a side wall of the chamber housing CH. The opening 204 may be provided as a passage for the substrate W to enter and exit the inside of the chamber housing CH. The opening 204 may be configured to be automatically opened and closed, for example, by a door assembly 205.

The door assembly 205 may be configured to include an outer door 206 and a door driver 207. The outer door 206 may open and close the opening 204 in an outer wall of the chamber housing CH. The outer door 206 may be moved in the height direction D3 of the substrate treating apparatus 200 under the control of the door driver 207. The door driver 207 may be operated using at least one element selected from a motor, a hydraulic cylinder, and a pneumatic cylinder.

The substrate support unit 210 is installed in an inner lower area of the chamber housing CH. The substrate support unit 210 may absorb and support the substrate W using an electrostatic force. For example, the substrate support unit 210 may be provided as an electrostatic chuck (ESC). However, the substrate support unit 210 is not limited thereto, and may also support the substrate W using various other methods such as vacuum, mechanical clamping, etc.

When the substrate support unit 210 is provided as the electrostatic chuck (ESC), the substrate support unit 210 may be configured to include a base plate 211 and a dielectric layer 212. The dielectric layer 212 may be disposed on the base plate 211 and may absorb and support the substrate W seated thereon. The base plate 211 may be formed of a material with excellent corrosion resistance and heat resistance. The base plate 211 may be provided as an aluminum body, for example. The dielectric layer 212 may be formed of, for example, ceramic as a material and may be provided as a ceramic puck.

Although not illustrated in FIG. 4, the substrate support unit 210 may be configured to further include a bonding layer. The bonding layer may bond the base plate 211 and the dielectric layer 212. The bonding layer may be formed to include a polymer, for example.

A ring structure 213 is provided to surround an outer edge area of the dielectric layer 212. When the plasma process is performed inside the chamber housing CH, the ring structure 213 may serve to concentrate ions onto the substrate W. The ring structure 213 may be formed of silicon as a material. The ring structure 213 may be provided as, for example, a focus ring.

Although not illustrated in FIG. 4, the ring structure 213 may further include an edge ring. The edge ring may be provided on a lower or outer side of the focus ring. The edge ring may serve to prevent a side surface of the dielectric layer 212 from being damaged by plasma. The edge ring may be formed of an insulating material, such as ceramic or quartz as a material.

A heating member 214 and a cooling member 215 are provided to maintain the substrate W at a process temperature, when the substrate treating process is performed inside the chamber housing CH. The heating member 214 may be installed inside the dielectric layer 212 and may be provided as a heating wire. The cooling member 215 may be installed inside the base plate 211 and may be provided as a cooling pipe through which a refrigerant moves. A chiller 216 may supply the refrigerant to the cooling member 215. The chiller 216 may use a cooling water as the refrigerant, but is not limited thereto and may also use helium (He) gas. Alternatively, the chiller 216 may also use both the cooling water and the helium gas as the refrigerant. Meanwhile, the heating member 214 may also not be provided within the substrate support unit 210.

The cleaning gas supply unit 220 provides a cleaning gas to the dielectric layer 212 or the ring structure 213 to remove foreign substances remaining in the dielectric layer 212 or the ring structure 213. For example, the cleaning gas supply unit 220 may provide nitrogen (N2) gas as the cleaning gas.

The cleaning gas supply unit 220 may include a cleaning gas supply source 221 and a cleaning gas supply pipe 222. The cleaning gas supply pipe 222 may be connected to a space between the dielectric layer 212 and the ring structure 213. The cleaning gas supplied by the cleaning gas supply source 221 may move into the space between the dielectric layer 212 and the ring structure 213 through the cleaning gas supply pipe 222 to remove foreign substances remaining on an edge portion of the dielectric layer 212 or an upper portion of the ring structure 213.

The process gas supply unit 230 provides a process gas to the internal space of the chamber housing CH. The process gas supply unit 230 may provide the process gas to the internal space of the chamber housing CH through a hole formed by penetrating through an upper cover of the chamber housing CH, i.e., the window module WM. However, the process gas supply unit 230 is not limited thereto, and may also provide the process gas to the internal space of the chamber housing CH through a hole formed by penetrating through the side wall of the chamber housing CH.

The process gas supply unit 230 may include a process gas supply source 231 and a process gas supply pipe 232. The process gas supply source 231 may provide a gas used to treat the substrate W as the process gas. The process gas supply source 231 may be provided as a single source within the substrate treating apparatus 200, but is not limited thereto and may also be provided as a plurality of sources. When a plurality of process gas supply sources 231 are provided within the substrate treating apparatus 200, the plurality of process gas supply sources may provide the same type of process gas, but are not limited thereto and may also provide different types of process gases.

The shower head unit 240 sprays the process gas provided from the process gas supply source 231 onto an entire area of the substrate W disposed in the internal space of the chamber housing CH. The shower head unit 240 may be connected to the process gas supply source 231 through the process gas supply pipe 232.

The shower head unit 240 may be disposed in the internal space of the chamber housing CH and may include a plurality of gas feeding holes 242. The plurality of gas feeding holes 242 may be formed by penetrating through a surface of a main body 241 in the up-down direction D3. The plurality of gas feeding holes 242 may be formed to be spaced apart from each other at regular intervals on the main body 241. The shower head unit 240 may uniformly spray the process gas over the entire area of the substrate W through the plurality of gas feeding holes 242.

The shower head unit 240 may be installed so as to face the substrate support unit 210 in the up-down direction D3 within the chamber housing CH. The shower head unit 240 may be provided to have a larger diameter than the dielectric layer 212. However, the shower head unit 240 is not limited thereto, and may also be provided to have the same diameter as the dielectric layer 212. The shower head unit 240 may be formed of silicone as a material, but is not limited thereto and may also be formed of metal as a material.

Although not illustrated in FIG. 4, the shower head unit 240 may be divided into a plurality of units. For example, the shower head unit 240 may be divided into three modules such as a first head module, a second head module, and a third head module. The first head module may be disposed at a position corresponding to a center zone of the substrate W. The second head module may be disposed to surround an outer edge of the first head module. The second head module may be disposed at a position corresponding to a middle zone of the substrate W. The third head module may be disposed to surround an outer edge of the second head module. The third head module may be disposed at a position corresponding to an edge zone of the substrate W.

The plasma generation unit 250 generates plasma from gas remaining in a discharge space. Here, the discharge space may be the internal space of the chamber housing CH and may be a space formed between the shower head unit 240 and the window module WM. Alternatively, the discharge space may be a space formed between the substrate support unit 210 and the shower head unit 240. When the discharge space is the space formed between the substrate support unit 210 and the shower head unit 240, the discharge space may be divided into a plasma area and a process area. The plasma area may be formed above the process area.

The plasma generation unit 250 may generate plasma in the discharge space using an inductively coupled plasma (ICP) source. For example, the plasma generation unit 250 may generate plasma in the discharge space by using the substrate support unit 210 and the antenna unit 280 as a first electrode (lower electrode) and a second electrode (upper electrode), respectively.

However, the present exemplary embodiment is not limited thereto. The plasma generation unit 250 may also generate plasma in the discharge space using a capacitively coupled plasma (CCP) source. For example, the plasma generation unit 250 may generate plasma in the discharge space by using the substrate support unit 210 and the shower head unit 240 as a first electrode (lower electrode) and a second electrode (upper electrode), respectively. Here, the case where the plasma generation unit 250 is provided as the ICP source will be described, and the case where the plasma generation unit 250 is provided as the CCP source will be described later.

The plasma generation unit 250 may be configured to include a first high-frequency power source 251, a first transmission line 252, a second high-frequency power source 253, and a second transmission line 254.

The first high-frequency power source 251 applies RF power to the first electrode. The first high-frequency power source 251 may serve as a plasma source that generates the plasma within the chamber housing CH. However, the first high-frequency power source 251 is not limited thereto, and may also serve to control characteristics of the plasma within the chamber housing CH together with the second high-frequency power source 253.

A plurality of first high-frequency power sources 251 may be provided within the substrate treating apparatus 200. In this case, the plasma generation unit 250 may include a first matching network electrically connected to each of the first high-frequency power sources. When different magnitudes of frequency powers are input from the plurality of first high-frequency power sources, the first matching network may serve to match the frequency powers and apply the matched frequency power to the first electrode.

The first transmission line 252 may connect the first electrode and GND. The first high-frequency power source 251 may be installed on the first transmission line 252. However, the first transmission line 252 is not limited thereto, and may also connect the first electrode and the first high-frequency power source 251. The first transmission line 252 may be provided as, for example, an RF rod.

The second high-frequency power source 253 applies RF power to the second electrode. The second high-frequency power source 253 may serve to control characteristics of the plasma within the chamber housing CH. For example, the second high-frequency power source 253 may serve to control ion bombardment energy within the chamber housing CH.

A plurality of second high-frequency power sources 253 may be provided within the substrate treating apparatus 200. In this case, the plasma generation unit 250 may include a second matching network electrically connected to each of the second high-frequency power sources. When different magnitudes of frequency powers are input from the plurality of second high-frequency power sources, the second matching network may serve to match the frequency powers and apply the matched frequency power to the second electrode.

The second transmission line 254 may connect the second electrode and GND. The second high-frequency power source 253 may be installed on the second transmission line 254.

The liner unit 260 is also defined as a wall liner, and protects the inside of the chamber housing CH from arc discharge generated during a process of exciting the process gas or impurities generated during the substrate treating process. The liner unit 260 may be formed to cover an inner side wall of the chamber housing CH.

The liner unit 260 may include a support ring 262 on an upper portion of the main body 261. The support ring 262 may protrude in an outer direction D1 from the upper portion of the main body 261 and may serve to secure the main body 261 to the chamber housing CH.

The baffle unit 270 serves to exhaust process byproducts and unreacted gases from the plasma inside the chamber housing CH to the outside. The baffle unit 270 may be installed in a space between the substrate support unit 210 and the inner side wall (or the liner unit 260) of the chamber housing CH, and may be installed to be adjacent to the exhaust hole 201. The baffle unit 270 may be provided in an annular ring shape between the substrate support unit 210 and the inner side wall of the chamber housing CH.

The baffle unit 270 may include a plurality of slot holes penetrating through the main body in the up-down direction D3 to control the flow of process gas within the chamber housing CH. The baffle unit 270 may be formed of a material having etching resistance to minimize damage or deformation by radicals, etc. in the internal space of the chamber housing CH in which the plasma is generated. For example, the baffle unit 270 may be formed to include quartz.

The window module WM serves as an upper cover of the chamber housing CH to seal the internal space of the chamber housing CH. The window module WM may be provided separately from the chamber housing CH, but is not limited thereto and may also be provided integrally with the chamber housing CH. A window module WM may be formed as a dielectric window using an insulating material. For example, the window module WM may be formed of alumina as a material. The window module WM may also include a coating film on a surface thereof to suppress the generation of particles, when the plasma process is performed in the internal space of the chamber housing CH.

The antenna unit 280 generates a magnetic field and an electric field inside the chamber housing CH to excite the process gas into plasma. The antenna unit 280 may operate using the RF power supplied from the second high-frequency power source 253.

The antenna unit 280 may be provided on the chamber housing CH. For example, the antenna unit 280 may be provided on the window module WM. However, the antenna unit 280 is not limited thereto, and may also be provided on the side wall of the chamber housing CH.

The antenna unit 280 may include an antenna 282 inside or on a surface of a main body 281. The antenna 282 may be provided to form a closed loop using a coil. The antenna 282 may be formed in a spiral shape or other various shapes along the width direction D1 of the chamber housing CH.

The antenna unit 280 may be formed to have a planar type. However, the antenna unit 280 is not limited thereto, and may also be formed to have a cylindrical type. When the antenna unit 280 is formed to have the planar type, the antenna unit 280 may be provided on the chamber housing CH. When the antenna unit 280 is formed to have the cylindrical type, the antenna unit 280 may be provided to surround an outer side wall of the chamber housing CH.

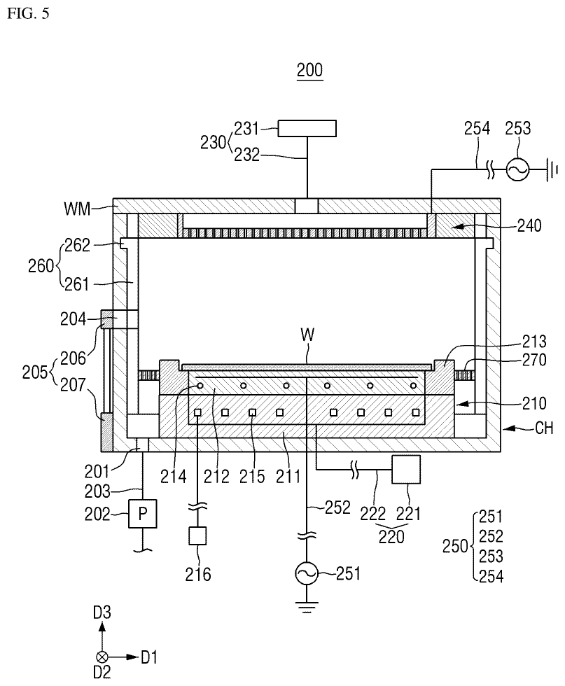

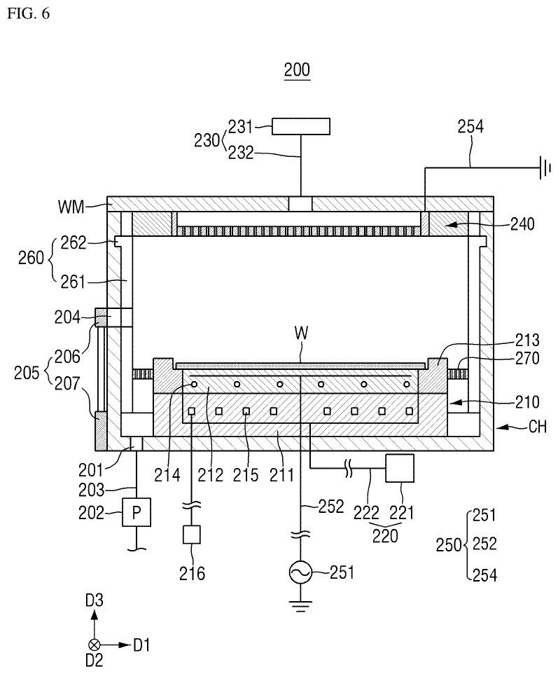

Hereinabove, the case in which the plasma generation unit 250 is provided as the ICP source has been described with reference to FIG. 4. Hereinafter, the case in which the plasma generation unit 250 is provided as the CCP source will be described with reference to FIGS. 5 and 6. In the following, compared to the case of FIG. 4, the description of the overlapping portions will be omitted and only the portions corresponding to the differences will be described.

FIG. 5 is a cross-sectional view exemplarily illustrating an internal structure of a substrate treating apparatus according to a second exemplary embodiment. In addition, FIG. 6 is a cross-sectional view exemplarily illustrating an internal structure of a substrate treating apparatus according to a third exemplary embodiment.

Referring to FIGS. 5 and 6, a substrate treating apparatus 200 may be configured to include a chamber housing CH, a substrate support unit 210, a cleaning gas supply unit 220, a process gas supply unit 230, a shower head unit 240, a plasma generation unit 250, a liner unit 260, a baffle unit 270, and a window module WM. That is, the substrate treating apparatus 200 of FIGS. 5 and 6 may not include the antenna unit 280 compared to the substrate treating apparatus 200 of FIG. 4.

The plasma generation unit 250 may be configured to include a first high-frequency power source 251, a first transmission line 252, a second high-frequency power source 253, and a second transmission line 254, as illustrated in FIG. 5. However, the plasma generation unit 250 is not limited thereto and may also be configured to include a first high-frequency power source 251, a first transmission line 252, and a second transmission line 254, as illustrated in FIG. 6. That is, the plasma generation unit 250 of FIG. 6 may not include the second high-frequency power source 253 compared to the plasma generation unit 250 of FIG. 5.

In the example of FIG. 4, the second transmission line 254 may be connected to the antenna 282 of the antenna unit 280. The second high-frequency power source 253 may apply the RF power to the antenna 282 of the antenna unit 280. In the example of FIG. 5, the second transmission line 254 may be connected to the main body 241 of the shower head unit 240. The second high-frequency power source 253 may apply the RF power to the main body 241 of the shower head unit 240.

In the example of FIG. 5, the second high-frequency power source 253 may be installed on the second transmission line 254. In the example of FIG. 6, the second high-frequency power source 253 may not be installed on the second transmission line 254. When the second high-frequency power source 253 is installed on the second transmission line 254, the plasma generation unit 250 may apply multiple frequencies to the substrate treating apparatus 200.

The shower head unit 240 may be provided as a shower head assembly including a base plate, a shower head, a gas distribution plate, and a heater/cooling plate. The shower head unit 240 may be provided as an upper electrode module within the substrate treating apparatus 200. Hereinafter, the shower head assembly will be described.

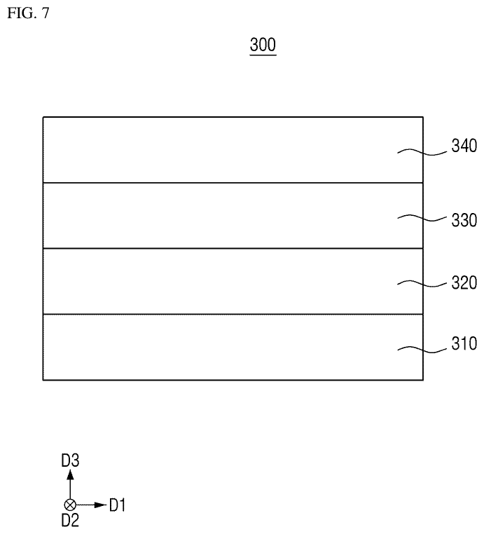

FIG. 7 is an exemplary view for describing a structure of a shower head assembly according to an exemplary embodiment of the present disclosure. Referring to FIG. 7, the shower head assembly 300 may be configured to include a lower plate 310, a shower head 320, a gas distribution plate 330, and an upper plate 340.

The lower plate 310 is a base plate and may be positioned at the lowest portion in the third direction D3 when installed in the substrate treating apparatus 200. The lower plate 310 may be fixed within the substrate treating apparatus 200. The lower plate 310 may not be detached and reattached when replacing the shower head 320.

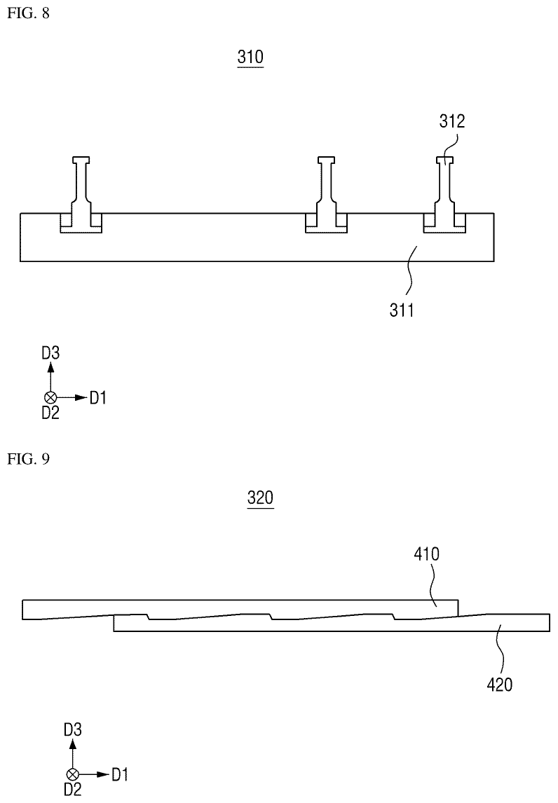

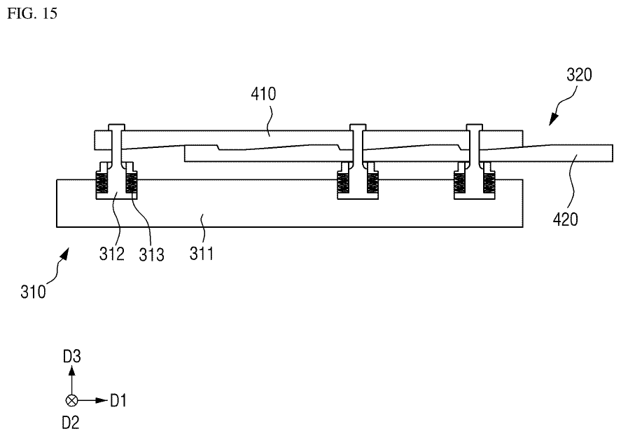

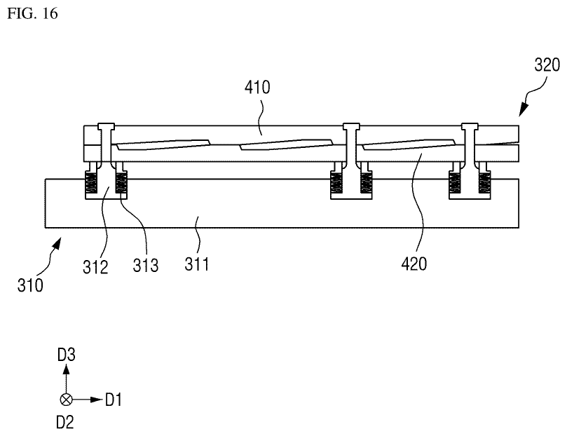

Referring to FIG. 8, the lower plate 310 may be configured to include a third main body 311 and a stud 312. The third main body 311 may have a flat shape. The stud 312 may protrude upward from an upper surface of the third main body 311. A plurality of studs 312 may be provided on the third main body 311. The stud 312 may be inserted into a groove formed on the upper surface of the third main body 311. As will be described later, the shower head 320 may be connected to the lower plate 310 through the stud 312. Referring to FIGS. 15 and 16, an elastic body 313 may be positioned within the groove of the third main body 311 so that the stud 312 may elastically move when a fastening is made between the lower plate 310 and the shower head 320. The elastic body 313 may be disposed below the stud 312 within the groove. Alternatively, the elastic body 313 may be disposed around the stud 312 within the groove. For example, the elastic body 313 may be a spring. FIG. 8 is an exemplary view for describing a structure of a lower plate constituting the shower head assembly according to an exemplary embodiment of the present disclosure.

The description will be made with reference to FIG. 7 again.

The shower head 320 may be disposed on the lower plate 310 when installed within the substrate treating apparatus 200. The shower head 320 may include a plurality of gas feeding holes to provide the process gas into the internal space of the chamber housing CH. The lower plate 310 also includes a plurality of gas feeding holes. The gas feeding holes formed in the shower head 320 and the gas feeding holes formed in the lower plate 310 may be mutually penetrable and may be formed with the same size.

The shower head 320 is positioned at a gas spray end within the substrate treating apparatus 200 using plasma, and serves as a process gas spray and electrode. Since the shower head 320 is directly exposed to the internal space of the chamber housing CH in which the substrate treating process is performed, it needs to be replaced after being used for a certain period of time.

The shower head 320 may be replaced after the substrate treating process is performed multiple times. A used shower head may be detached from the lower plate 310, and an unused shower head may be attached on the lower plate 310. The lower plate 310 is not replaced, and only the shower head 320 may be replaced. The lower plate 310 may be formed by including an etching resistant material or a plasma resistant material.

Referring to FIG. 9, the shower head 320 may be configured to include a first plate 410 and a second plate 420. The second plate 420 may be disposed above the first plate 410. A lower surface of the second plate 420 may be in contact with an upper surface of the first plate 410. A portion of the lower surface of the second plate 420 may be formed to engage with a portion of the upper surface of the first plate 410. The second plate 420 may be formed of the same material as the first plate 410, but is not necessarily limited thereto. FIG. 9 is an exemplary view for describing a structure of a shower head according to a first exemplary embodiment of the present disclosure.

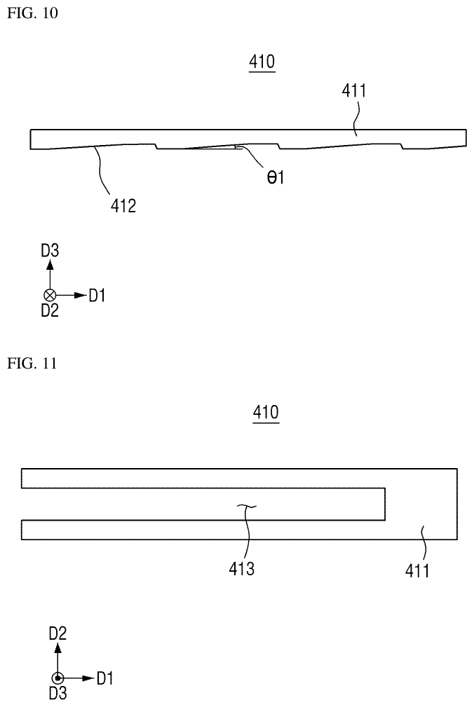

FIG. 10 is a first exemplary view for describing a first plate constituting the shower head according to the first exemplary embodiment of the present disclosure. FIG. 11 is a second exemplary view for describing the first plate constituting the shower head according to the first exemplary embodiment of the present disclosure. The first plate 410 of the shower head 320 may be formed as illustrated in FIG. 10 when viewed from a side. The first plate 410 of the shower head 320 may be formed as illustrated in FIG. 11 when viewed from above.

Referring to FIGS. 10 and 11, the first plate 410 may be configured to include a first main body 411 and a first inclined portion 412. The first inclined portion 412 may be formed on a surface of the first main body 411. The first inclined portion 412 may be formed on a lower surface of the first main body 411. A plurality of first inclined portions 412 may be formed along the length direction D1 of the first main body 411. The plurality of first inclined portions may have the same inclination angle. The plurality of first inclined portions may be formed to have an inclination angle of θ₁.

A first groove 413 may be formed to be long at one end of the first main body 411. The first groove 413 may be formed along the length direction D1 of the first main body 411. One side of the first main body 411 having the first groove 413 formed may be opened, but the other side thereof may not be opened.

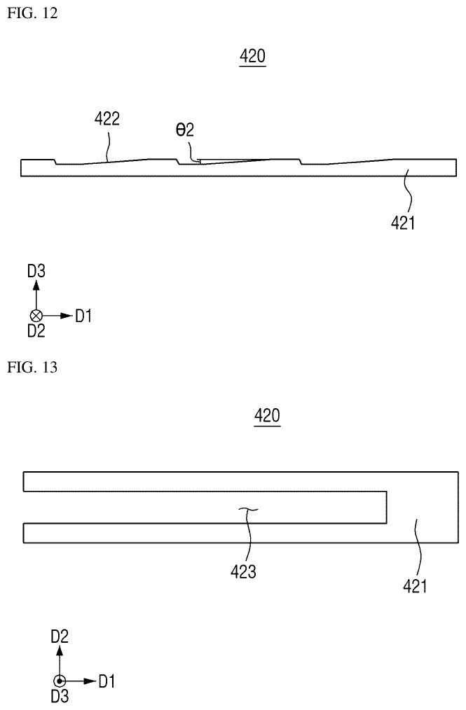

FIG. 12 is a first exemplary view for describing a second plate constituting the shower head according to the first exemplary embodiment of the present disclosure. FIG. 13 is a second exemplary view for describing the second plate constituting the shower head according to the first exemplary embodiment of the present disclosure. The second plate 420 of the shower head 320 may be formed as illustrated in FIG. 12 when viewed from a side. The second plate 420 of the shower head 320 may be formed as illustrated in FIG. 13 when viewed from above.

Referring to FIGS. 12 and 13, the second plate 420 may be configured to include a second main body 421 and a second inclined portion 422. The second inclined portion 422 may be formed on a surface of the second main body 421. The second inclined portion 422 may be formed on an upper surface of the second main body 421. The second inclined portion 422 may have a shape that engages with the first inclined portion 412. A plurality of second inclined portions 422 may be formed along the length direction D1 of the second main body 421. The plurality of second inclined portions may have the same inclination angle. The plurality of second inclined portions may be formed to have an inclination angle of θ₂. The plurality of second inclined portions may have the same inclination angle as the plurality of first inclined portions.

A second groove 423 may be formed to be long at one end of the second main body 421. The second groove 423 may be formed along the length direction D1 of the second main body 421. One side of the second main body 421 having the second groove 423 formed may be opened, but the other side thereof may not be opened. The second groove 423 may be formed so that the same side as the first groove 413 is opened. The second groove 423 may have the same size as the first groove 413.

The shower head 320 is first stacked on an upper lead plate while being assembled to the gas distribution plate 330 with a fastener including bolts. In order to replace the shower head 320 that has been used for a certain number of cycles in such a stacked structure, all stacked assemblies need to be detached. Since a wide range of detachment and attachment takes place during such a process, there is a problem that it requires a lot of man-hours and has poor reproducibility.

In addition, a thermally conductive pad that requires compression is inserted between the stacked assemblies, and the pad may not reused due to permanent deformation after a single detachment process. Therefore, as the shower head 320 is replaced, the number of pads consumed increases, which leads to increased maintenance costs.

In addition, due to the characteristics of the substrate treating apparatus 200, in an environment where heating and cooling are repeated, the assembly through bolt tightening is subject to loosening due to vibration. Depending on the degree of loosening that has been subjected, a fastening force decreases, which causes a change in temperature of the shower head 320, thereby affecting the substrate treating process.

The present disclosure provides an assembly method that facilitates replacement of the shower head 320 and provides a constant fastening force even under repeated thermal shock.

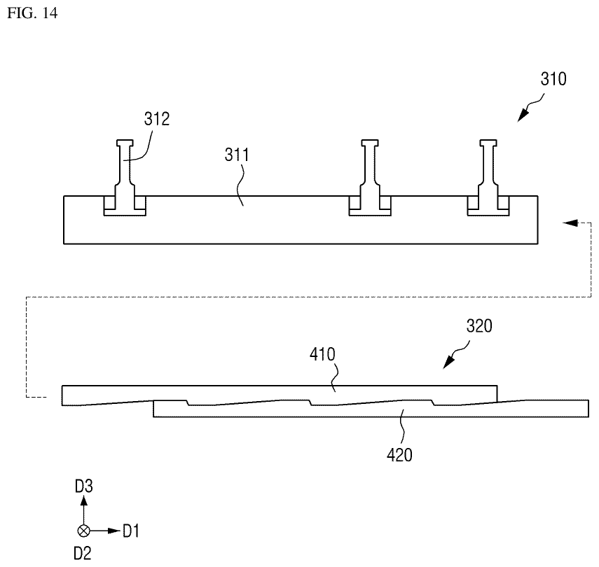

Next, a method of fastening the shower head 320 will be described. FIG. 14 is a first exemplary view for describing a fastening process between the shower head and the lower plate according to the first exemplary embodiment of the present disclosure. FIG. 15 is a second exemplary view for describing the fastening process between the shower head and the lower plate according to the first exemplary embodiment of the present disclosure. FIG. 16 is a third exemplary view for describing the fastening process between the shower head and the lower plate according to the first exemplary embodiment of the present disclosure.

According to the present disclosure, the shower head assembly 300 enables replacement of only the shower head 320 without requiring detachment of the assemblies positioned above and below the shower head 320, i.e., the lower plate 310, the gas distribution plate 330, and the upper plate 340.

Referring to FIG. 14, when the shower head assembly 300 is initially installed within the substrate treating apparatus 200, the lower plate 310 is installed within the substrate treating apparatus 200, and then the shower head 320 is fastened to the lower plate 310. The lower plate 310 may have a plurality of studs 312 installed in the vertical direction on the third main body 311, and the shower head 320 may be connected to the lower plate 310 through the plurality of studs 312.

When replacing the shower head 320, the lower plate 310 may not be detached and reattached within the substrate treating apparatus 200. The lower plate 310 may be fixed within the substrate treating apparatus 200 when being initially installed. That is, only the shower head 320 may be detached and reattached. When replacing the shower head 320, the shower head 320 may be positioned on the side surface of the lower plate 310 and the shower head 320 may be moved in the horizontal direction D1. The shower head 320 may be fastened to the lower plate 310 by passing through the plurality of studs 312 in sequence.

Referring to FIGS. 15 and 16, by inserting two plates 410 and 420 with an inclination and then sliding the second plate 420 positioned below in a centrifugal direction, the fastening between the lower plate 310 and the shower head 320 may be completed.

The first plate 410 and the second plate 420 may include a repetitive pattern of inclined portions 412 and 422 on surfaces that are in contact with each other. Referring to FIG. 15, since the first plate 410 and the second plate 420 completely overlap at the time of the initial insertion, the plates 410 and 420 may be inserted inward without interference as the total height of the two plates 410 and 420 is lower than the protruding height of the stud 312. Referring to FIG. 16, when the lower plate 420 is then completely slid in the center direction, the total height of the two plates 410 and 420 increases by the height in the vertical height D3 of the inclined portions 412 and 422, and the stud 312 fastened to the shower head 320 may be pulled and tightened by the amount of displacement that occurs at this time. The first plate 410 and the second plate 420 may prevent movement of the two plates 410 and 420 and prevent deformation of the two plates 410 and 420 by having the flat portions, not the inclined portions 412 and 422, in contact with each other.

During the process of fastening the shower head 320, the stud 312 assembled to the shower head 320 may be lifted by the upper first plate 410 among the two plates 410 and 420, and may not be subject to a lateral force.

As described above, the first inclined portion 412 of the first plate 410 and the second inclined portion 422 of the second plate 420 may be formed to engage with each other. After the first inclined portion 412 and the second inclined portion 422 are fastened to the lower plate 310 through the stud 312 in the state in which they are formed to be engaged with each other, the shower head 320 may be fixed by the lower plate 310 and the gas distribution plate 330 positioned above and below by the sliding motion of the second plate 420 in the horizontal direction D1.

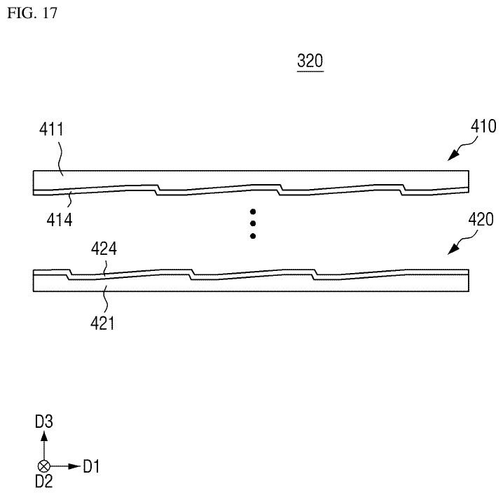

Referring to FIG. 17, to reduce friction between the first plate 410 and the second plate 420 while the sliding motion of the second plate 420 is being performed, a first coating layer 414 may be formed on the surface of the first inclined portion 412. Similarly, a second coating layer 424 may be formed on the surface of the second inclined portion 422.

The first coating layer 414 and the second coating layer 424 may serve as lubricants while the sliding motion of the second plate 420 is performed. The first coating layer 414 and the second coating layer 424 may be formed to include a fluorine component. For example, the first coating layer 414 and the second coating layer 424 may be formed by coating using a fluorine-based resin. Alternatively, the first coating layer 414 and the second coating layer 424 may be formed by coating using Teflon resin. However, the present disclosure is not limited thereto, and a bearing may also be installed instead of the first coating layer 414 and the second coating layer 424. Although not illustrated in FIG. 17, the bearing may be installed between the first plate 410 and the second plate 420.

Meanwhile, both the first coating layer 414 and the second coating layer 424 do not need to be formed, and only one of the first coating layer 414 and the second coating layer 424 may be formed. FIG. 17 is an exemplary view for describing a structure of a shower head according to a second exemplary embodiment of the present disclosure.

The description will be made with reference to FIG. 7 again.

The gas distribution plate (GDP) 330 may be disposed on the shower head 320 when installed in the substrate treating apparatus 200. The gas distribution plate 330 can serve to distribute the process gas to each gas feeding hole in the shower head 320. The gas distribution plate 330 may be formed of a corrosion resistant metal. The gas distribution plate 330 may be formed of a plasma resistant metal. The gas distribution plate 330 may be formed of aluminum.

The upper plate 340 may be disposed on the gas distribution plate 330 when installed within the substrate treating apparatus 200. The upper plate 340 may be positioned at the uppermost portion within the shower head assembly 300.

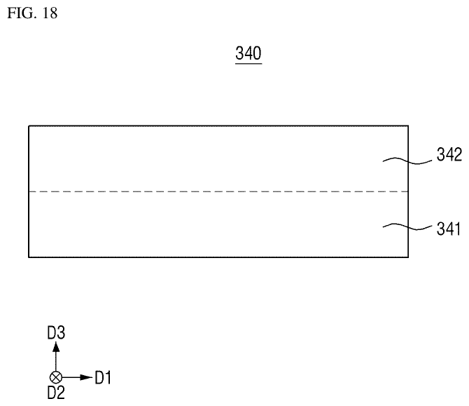

Referring to FIG. 18, the upper plate 340 may include a heating plate 341 and a cooling plate 342. The cooling plate 342 may be positioned above the heating plate 341. FIG. 18 is an exemplary view for describing a structure of an upper plate constituting the shower head assembly according to an exemplary embodiment of the present disclosure.

The present disclosure relates to a shower head assembly 300 using a plurality of plates having an inclined pattern engraved thereon. In the shower head assembly 300, it is possible to replace only the shower head 320 without detaching the upper parts 330 and 340. The shower head 320 may have an inclined surface of a repeated pattern. That is, the first plate 410 may include a plurality of first inclined portions 412, and the second plate 420 may include a plurality of second inclined portions 422. The shower head 320 may prevent movement of the members by having the flat surfaces that are in contact with each other after final fastening. The shower head 320 may adjust a fastening force by adjusting a vertical length of the inclined surface. The shower head 320 may simultaneously fasten a plurality of fastening points. The shower head 320 may not apply a lateral external force to a member directly connected thereto. The shower head 320 may have a low friction coefficient portion coated or configured on a friction portion.

To prevent the range of detachment and attachment from expanding when replacing the shower head 320, the shower head assembly 300 may be replaced from the side surface of the gas distribution plate 330 so as to be replaced without detaching the stacked assemblies 310, 330, and 340, thereby reducing work manpower and quickly performing the replacement.

If an external force in a lateral direction (i.e., a direction perpendicular to the central axis of the shower head cylinder) is applied to the shower head or the assembly connected thereto, it may cause fracture of a brittle material or an imbalance in the fastening force. The shower head assembly 300 may have structural stability because of applying only an external force in a longitudinal direction (i.e., in a direction of the center axis of the shower head cylinder).

Since the shower head assembly 300 is not assembled using the fastener, there is no change in the fastening force even if changes in thermal stress are repeatedly applied, and accordingly, changes in the fastening force according to the usage time of the substrate treating apparatus 200 may be prevented.

The exemplary embodiments of the present disclosure have been described above with reference to the accompanying drawings, but the present disclosure may be implemented in various different forms, and those skilled in the art to which the present disclosure pertains may understand that the present disclosure may be implemented in other specific forms without changing the technical concepts or features of the present disclosure. Therefore, it should be understood that the exemplary embodiments described above are illustrative in all aspects and not restrictive.

What is claimed is:

1. A substrate treating apparatus comprising:
a chamber housing providing a space for treating a substrate;
a substrate support unit disposed inside the chamber housing and supporting the substrate;
a shower head assembly disposed inside the chamber housing and providing a process gas; and
a plasma generation unit generating plasma for treating the substrate using the process gas,
wherein the shower head assembly includes:
a lower plate;
a shower head disposed on the lower plate;
a gas distribution plate disposed on the shower head; and
an upper plate disposed on the gas distribution plate, and
the shower head is detachable and attachable.

2. The substrate treating apparatus of claim 1, wherein when the shower head is replaced, the lower plate, the gas distribution plate, and the upper plate are not separated within the substrate treating apparatus.

3. The substrate treating apparatus of claim 1, wherein the shower head includes:
a first plate; and
a second plate disposed on the first plate and engaged with the first plate.

4. The substrate treating apparatus of claim 3, wherein the first plate includes:
a first main body formed along a length direction and including a groove penetrating in a direction perpendicular to the length direction; and
a first inclined portion formed on one surface of the first main body.

5. The substrate treating apparatus of claim 4, wherein the first inclined portion has a pattern that repeats along the length direction of the first main body.

6. The substrate treating apparatus of claim 4, wherein one side of the first main body is opened and connected to the groove.

7. The substrate treating apparatus of claim 4, wherein the second plate includes:
a second main body formed along a length direction and including a groove penetrating in a direction perpendicular to the length direction; and
a second inclined portion formed on one surface of the second main body.

8. The substrate treating apparatus of claim 7, wherein the second inclined portion has a pattern that repeats along the length direction of the second main body.

9. The substrate treating apparatus of claim 7, wherein one side of the second main body is opened and connected to the groove.

10. The substrate treating apparatus of claim 7, wherein the first inclined portion and the second inclined portion are respectively formed on the surfaces that are in contact with between the first main body and the second main body.

11. The substrate treating apparatus of claim 3, wherein the first plate and the second plate are inserted between the lower plate and the gas distribution plate while being engaged with each other.

12. The substrate treating apparatus of claim 11, wherein the second plate is inserted between the lower plate and the gas distribution plate, and then slides inwardly in the substrate treating apparatus.

13. The substrate treating apparatus of claim 4, wherein the first plate further includes a first coating layer formed on a surface of the first inclined portion and that is lubricated.

14. The substrate treating apparatus of claim 13, wherein the first coating layer includes a fluorine component.

15. The substrate treating apparatus of claim 7, wherein the second plate further includes a second coating layer formed on a surface of the second inclined portion and that is lubricated.

16. The substrate treating apparatus of claim 7, wherein the shower head further includes a bearing disposed between the first plate and the second plate.

17. The substrate treating apparatus of claim 1, wherein the lower plate includes:
a third main body; and
a plurality of studs inserted into grooves formed on a surface of the third main body and protruding from the surface of the third main body.

18. The substrate treating apparatus of claim 17, wherein the lower plate further includes an elastic body inserted into the groove and disposed below or around the stud.

19. A shower head assembly providing a process gas into a substrate treating apparatus, the shower head assembly comprising:
a lower plate;
a shower head disposed on the lower plate;
a gas distribution plate disposed on the shower head; and
an upper plate disposed on the gas distribution plate,
wherein the shower head includes:
a first plate; and
a second plate disposed on the first plate and engaged with the first plate,
the shower head is detachable and attachable, and
when the shower head is replaced, the lower plate, the gas distribution plate, and the upper plate are not separated within the substrate treating apparatus.

20. A substrate treating apparatus comprising:
a chamber housing providing a space for treating a substrate;
a substrate support unit disposed inside the chamber housing and supporting the substrate;
a shower head assembly disposed inside the chamber housing and providing a process gas; and
a plasma generation unit generating plasma for treating the substrate using the process gas,
wherein the shower head assembly includes:
a lower plate;
a shower head disposed on the lower plate;
a gas distribution plate disposed on the shower head; and
an upper plate disposed on the gas distribution plate,
the shower head includes:
a first plate; and
a second plate disposed on the first plate and engaged with the first plate,
the first plate and the second plate are inserted between the lower plate and the gas distribution plate while being engaged with each other,
the second plate is inserted between the lower plate and the gas distribution plate, and then slides inwardly in the substrate treating apparatus, and
when the shower head is replaced, the lower plate, the gas distribution plate, and the upper plate are not separated within the substrate treating apparatus.
